(19) United States
(12) Patent Application Publication
(10) Pub. No.: US 2026/0135059 A1
(43) Pub. Date: May 14, 2026

(54) MODULAR OPTICAL BENCH ASSEMBLY

(71) Applicant: FEI COMPANY, Hillsboro, OR (US)

(72) Inventors: Ronald Josephus Adrianus van Gastel, Tilburg (NL); Alexander Henstra, Utrecht (NL); Wilhelmus Johannes Maria Sterken, Netersel (NL)

(21) Appl. No.: 18/948,068

(22) Filed: Nov. 14, 2024

(51) Int. Cl. H01J 37/147; H01J 37/20

(52) U.S. Cl. CPC H01J 37/1478; H01J 37/20; H01J 2237/1207; H01J 2237/1516

(57) ABSTRACT

An optical bench assembly configured to be positioned in an optics chamber of a charged particle system. The optical bench assembly includes a housing defining a plurality of openings and a channel defining a beam axis for a charged particle beam and a plurality of optical holders. Each optical holder of the plurality of optical holders includes a base portion and one or more arms extending from the base portion, the one or more arms of each optical holder is removably mountable to the housing within a first opening of the plurality of openings, the base portion of each optical holder is configured to house a multipole element, and the base portion of each optical holder is positionable in the channel such that each multipole element is aligned with each other along the beam axis.

### BACKGROUND

Charged particle systems are used in a variety of applications including the manufacturing, repair, and inspection of miniature devices, such as integrated circuits, magnetic recording heads, and photolithography masks. One type of charged particle system may include an electron microscope. Electron microscopes are used as imaging tools by focusing an electron beam of a sufficient size from an electron emitter onto a focused location on a sample and then detecting the signal electrons (or photons) that are emitted from the sample at the focused location to generate a high-resolution image of the sample.

### BRIEF SUMMARY

One aspect of the disclosure provides for an optical bench assembly configured to be positioned in an optics chamber of a charged particle system. The optical bench assembly includes a housing defining a plurality of openings and a channel defining a beam axis for a charged particle beam and a plurality of optical holders. Each optical holder of the plurality of optical holders includes a base portion and one or more arms extending from the base portion, the one or more arms of each optical holder is removably mountable to the housing within a first opening of the plurality of openings, the base portion of each optical holder is configured to house a multipole element, and the base portion of each optical holder is positionable in the channel such that each multipole element is aligned with each other along the beam axis.

Implementations may include one or more of the following features. The one or more arms may include a plurality of arms. A first arm of the plurality of arms may be removably mountable within the first opening and a second arm of the plurality of arms may be removably mountable within a second opening of the plurality of openings. The second opening may include a larger cross-sectional area than the first opening. A third arm of the plurality of arms may be removably mountable within the second opening. Each optical holder of the plurality of optical holders may include a ball received in the one or more arms. The one or more arms may include a spring mechanism configured to engage the ball. The spring mechanism may be one of a cantilever or leaf spring. The housing may define a notch configured to receive the ball. The multipole element may include an electrostatic multipole element. The electrostatic multiple element may include one or more electrostatic einzel lenses.

One aspect of the disclosure provides for a charged particle system including a charged particle source configured to emit a charged particle beam along a beam axis and an optics chamber in fluid communication with the charged particle source. The optics chamber includes an optical bench assembly having a housing defining a plurality of opening and a channel aligned with the beam axis and an optical holder including a base portion and one or more arms extending from the base portion. A first arm of the one or more arms is coupled to the housing within a first opening of the plurality of openings and the base portion is positioned in the channel. The optics chamber also includes a multipole element housed in the base portion and aligned with the beam axis.

Implementations may include one or more of the following features. The one or more arms may include a plurality of arms, and a first arm of the plurality of arms may be removably mountable within the first opening and a second arm of the plurality of arms may be removably mountable within a second opening of the plurality of openings. Each arm of the plurality of arms may be substantially equiangular from each other about the base portion. The optics chamber may define a vacuum volume configured to be held under vacuum and the optical bench assembly may be positioned in the vacuum volume. Each optical holder of the plurality of optical holders may include a ball received in the one or more arms. The one or more arms may include a spring mechanism configured to engage the ball. The housing may define a notch configured to receive the ball. The multipole element may include an electrostatic multipole element.

One aspect of the disclosure provides for an optical holder configured to be positioned in an optical bench assembly of a charged particle system. The optical holder includes a plurality of balls, a base portion defining an optical aperture, and a plurality of arms extending from the base portion. Each arm of the plurality of arms defines an arm aperture and includes a lever mechanism, each ball of the plurality of balls is positioned in the aperture of each arm, and the lever mechanism of each arm is configured to engage the ball. The optical holder also includes an optical element housed in the optical opening.

### BRIEF DESCRIPTION OF THE DRAWINGS

A further understanding of the nature and advantages of various embodiments may be realized by reference to the following figures. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 depicts a simplified cross-sectional view of an example charged particle system, according to an embodiment of the disclosure.

FIG. 2 depicts an isometric view of an example optical bench assembly, according to an embodiment of the disclosure.

FIG. 3A depicts a top isometric view of an example optical holder and optical element, according to an embodiment of the disclosure.

FIG. 3B depicts a bottom isometric view of the example optical holder and optical element of FIG. 3A, according to an embodiment of the disclosure.

FIG. 4A depicts an isometric view of a first optical holder in a housing, according to an embodiment of the disclosure.

FIG. 4B depicts a side view of the first optical holder in the housing of FIG. 4A, according to an embodiment of the disclosure.

FIG. 4C depicts a cross-sectional view of the first optical holder in the housing of FIG. 4A along Section A-A, according to an embodiment of the disclosure.

FIG. 5 depicts a cross-sectional view of a first optical holder in a housing, according to an embodiment of the disclosure

FIG. 6 depicts a flowchart for generating an image according to an embodiment of the disclosure.

FIG. 7 depicts a block diagram of an example computer system usable with systems and methods, according to embodiments of the present disclosure.

### DETAILED DESCRIPTION

Charged particle systems that are used in electron microscopy provide high-resolution imaging by detecting signal electrons (e.g., backscattered electrons, secondary electrons, primary beam electrons that have passed through a sample, or the like) produced by the elastic and inelastic scattering of a beam of electrons emitted from an electron emitter that interact with atoms of a sample. In one example, the electrons may be emitted from a cathode electrode that is heated by an electric current. The emitted electrons are attracted to an anode placed downstream of the cathode electrode, thus forming an electron beam directed to, and interacting with, the sample. The current of the signal electrons emitted from the electron beam interacting with the sample are measured by one or more electron detectors. This current can be used to generate a high-resolution image of the sample.

Conventional charged particle systems can include optical elements used to adjust the beam profile of a charged particle beam (e.g., the beam’s structure, shape, path energy, or the like), such as correcting aberrations in an electron beam propagating through the beam column, shaping and controlling the electron beam, or the like. For example, such conventional systems may include optical systems having multipole lenses and magnetic coils to adjust the beam profile of the charged particle beam. However, such conventional optical systems introduce certain challenges.

For example, using magnetic coils greatly increases the size of the optical system, which can increase the complexity of the assembly and disassembly of the conventional optical system. Where the conventional optical system is modular, such that the multipole lenses and magnetic coils can be exchanged for other multipole lenses and magnetic coils, this increased complexity can mitigate the benefits of being able to exchange and move the multipole lenses and magnetic coils. For example, due to the increased size of the optical elements as a result of the magnetic coils, the magnetic coils are positioned outside of the vacuum volume that the electron beam propagates through in the beam column while also still having to interface with that vacuum volume. This interfacing can be delicate and ensuring that the magnetic coils properly interface with the vacuum volume can increase the complexity of replacing the magnetic coils. As such, it may be beneficial for certain charged particle systems to include an improved optical system.

The present disclosure addresses these issues by providing a charged particle system having an optical bench assembly that includes a housing receiving optical elements. The housing may be a single mechanical enclosure that allows for the optical elements to be modularly interchanged with other optical elements to support a variety of different optical designs. For example, the optical elements may be interchangeable within the housing with other optical elements to adjust the beam profile of a charged particle beam (e.g., an electron beam) flowing through the optical bench assembly (e.g., correcting or adjusting aberrations in the charged particle beam). The optical elements can also include standardized connection features to couple with the housing to increase the simplicity of interchanging the optical elements, decrease the complexity of adjusting the optical design of the optical bench assembly, and decrease manufacturing costs. The optical elements can also automatically align with the beam axis of the charged particle beam when being installed within the housing to further decrease the complexity of interchanging the optical elements within the housing. The optical elements can include electrostatic multipole elements, which greatly reduces the size of the optical bench assembly. As a result, the optical bench assembly can be positioned in the vacuum volume of the beam column and does not require that the optical bench assembly be properly interfaced with the vacuum volume as in conventional systems. This can greatly decrease the complexity in adjusting the optical elements of the optical bench assembly as well as increasing the speed at which the multipole elements are replaced and/or adjusted within the optical bench assembly. As a result, the optical bench assembly can increase the versatility of the microscope by allowing for the microscope to be quickly configured for different uses.

Although the remaining portions of the description will routinely reference transmission electron microscopes (TEM), it will be readily understood by the skilled artisan that the technology is not so limited. The present designs may be employed with other types of charged particle microscopes, such as scanning electron microscopes (SEM), scanning transmission electron microscopes (STEM), focused ion beam (FIB) microscopes, dual beam systems including an ion beam source and an electron beam source, reflection electron microscopes (REM), circuit editing microscopes, secondary ion mass spectrometry (SIMS) microscopes, or the like. Accordingly, the disclosure and claims are not to be considered limited to any particular example microscope discussed, but can be utilized broadly with any number of electron microscopes that may exhibit some or all of the electrical or chemical characteristics of the discussed examples.

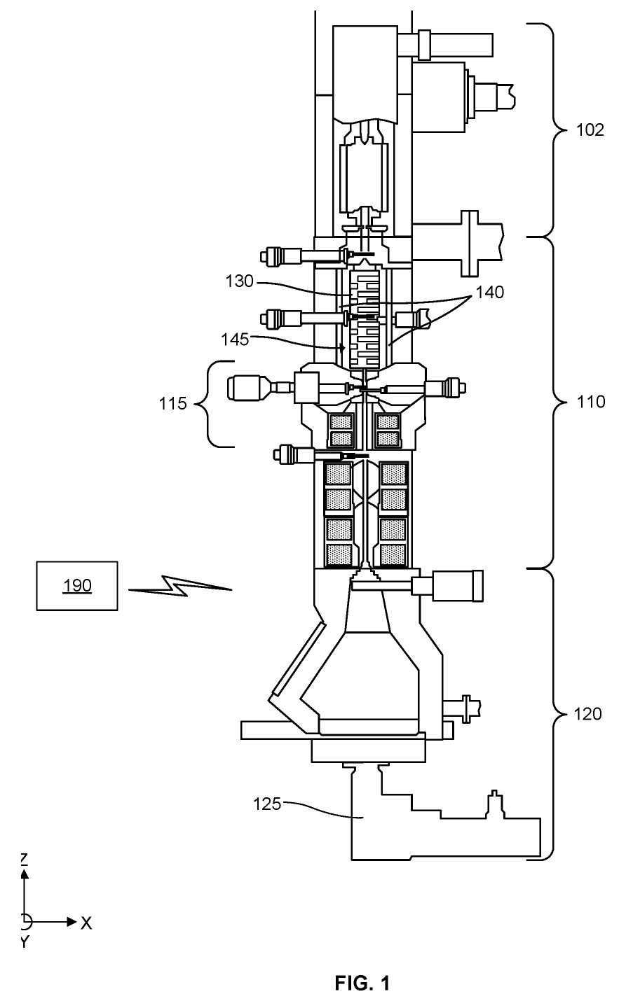

FIG. 1 is a schematic diagram illustrating an example charged particle system 100, in accordance with some embodiments of the present disclosure. In the following description, details of certain internal components and functions of the example charged particle system 100 are omitted for simplicity and to focus description on to embodiments of the present disclosure. The example charged particle system 100 includes a source section 102, a beam column 110, an objective section 115, and an imaging section 120. The charged particle system 100 may be in electronic communication with a computer system 190 such that electronic information may be exchanged between the charged particle system 100 and the computer system 190 (e.g., data, measurements, instructions, or the like).

The source section 102 may include electronics configured to energize a source of charged particles (e.g., a cathode electrode or the like), which can include a high-voltage field-emission source or other sources of emitted electrons, such that a charged particle beam (e.g., an electron beam) is formed and conducted through a vacuum into the beam column 110. The beam column 110 includes components for beam forming, including electromagnetic lenses and/or electrostatic lenses, and multiple apertures to control properties of the beam of electrons. The beam column 110 components may include condenser lenses, objective lenses, projector lenses, aberration correctors, deflectors, stigmators, among others, as well as corresponding apertures. The objective section 115 can host a sample through which the charged particle beam can be transmitted. The objective section 115 can include one or more types of detectors, such as x-ray detectors, secondary electron detectors, or the like. The imaging section 120 can include one or more types of detectors, sensors, screens, and/or optics configured to generate images, spectra, and other data for use in sample imaging and/or microanalysis. For example, the imaging section can include a scintillator screen, binoculars, transmission electron microscopy (TEM) detector(s) (e.g., pixelated electron detector, secondary electron detector, camera(s), or the like), segmented STEM detector(s), and electron energy loss spectroscopy (EELS) spectrometer(s) 125, among others.

The charged particle beam is typically characterized by a beam current and an accelerating voltage applied to generate the beam, among other criteria. The ranges of beam current and accelerating voltage can vary between instruments and are typically selected based on material properties of the sample or the type of analysis being conducted. Generally, however, charged particle beams are characterized by an energy from about 0.1 keV (e.g., for an accelerating voltage of 0.1 kV) to about 50 keV and a beam current from picoamperes to microamperes. The charged particle beam can propagate from the source section 102, and through the beam column 110 and objective section 115 along a beam axis (e.g., along a Z-axis).

As noted above, conventional charged particle systems may include optical elements that can adjust the beam profile of the charged particle beam, such as correcting aberrations of the charged particle beam, shaping and controlling the electron beam, or the like. However, these conventional optical elements include magnetic coils that drastically increase the size of the optical elements and which, as a result, leads to these optical elements being positioned outside of the vacuum volume of the beam column. Both of these factors can increase the complexity of adjusting the optical elements in the conventional charged particle systems, such as where the optical elements are modular).

The charged particle system 100 may include an optical bench assembly 130 positioned in the beam column 110 that addresses these issues. For example, in some embodiments, the optical bench assembly 130 may not include magnetic coils and, instead, may include electrostatic optical elements. This can result in a drastically reduced size compared to conventional optical elements, especially in a cross-sectional diameter. Additionally, as the optical bench assembly 130 is smaller, the optical bench assembly 130 may be positioned in a vacuum volume 145 within the beam column 110 defined by a liner tube 140 within the beam column 110. This may allow for the optical bench assembly 130 to be adjusted more easily compared to conventional optical elements. Although the optical bench assembly 130 is depicted as being positioned upstream of the objective section 115, in other embodiments, the optical bench assembly, and/or a second optical bench assembly, may be positioned downstream of the objective section.

The vacuum within the vacuum volume 145 may be formed by a vacuum pump (not shown in FIG. 1) in fluid communication with the interior of the liner tube 140. The vacuum volume 145 may be beneficial to minimize undesirable particles from interfering with the propagation of the charged particle beam flow through the liner tube 140. In other embodiments, there may be no liner tube and the vacuum volume may be defined by the beam column. The liner tube 140 may be made of one or more layers that can act as a magnetic shield such that external magnetic fields may be blocked from interfering within the vacuum volume 145 (e.g., of ferromagnetic materials or the like), such as blocking external magnetic fields from interfering with the optical bench assembly 130.

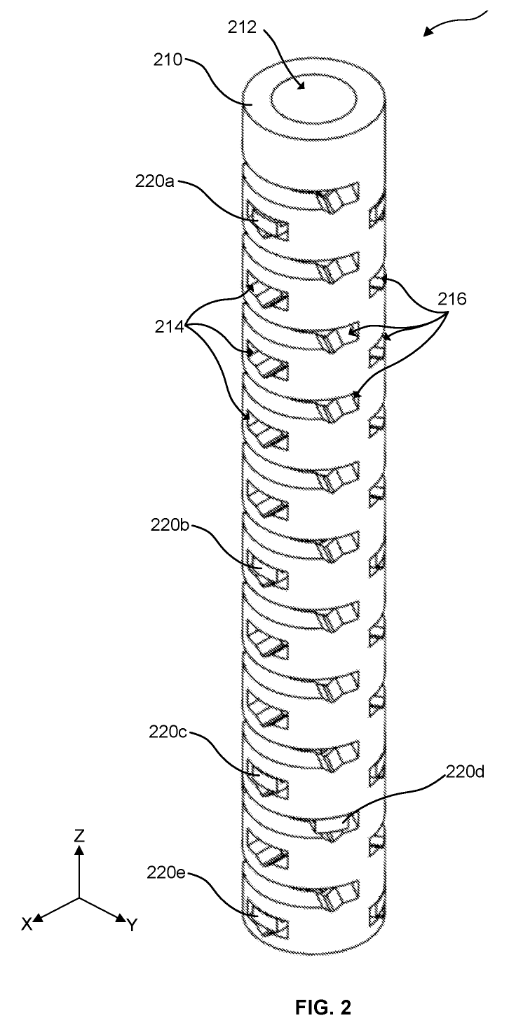

FIG. 2 depicts the optical bench assembly 130 used in the charged particle system 100. The optical bench assembly 130 may include a first optical holder 220a, a second optical holder 220b, a third optical holder 220c, a fourth optical holder 220d, and a fifth optical holder 220e coupled to a housing 210. As will be discussed further below, each of the optical holders 220a, 220b, 220c, 220d, 220e may house an optical element (e.g., a multipole element) that are aligned together. The optical elements can be aligned with the beam axis of a charged particle beam within a channel 212 defined by the housing 210 such that a charged particle beam can propagate through the optical elements along the beam axis. The optical elements of each of the optical holders 220a, 220b, 220c, 220d, 220e can adjust the beam profile of the charged particle beam for a variety of uses, such as correcting aberrations of the charged particle beam (e.g., path aberrations, spherical aberrations, or the like), shaping and controlling the electron beam, or the like.

The optical bench assembly 130 can be modular such that the number and position of the optical holders 220a, 220b, 220c, 220d, 220e in the housing 210 can be adjusted corresponding to a desired beam profile of the charged particle beam. For example, the number of optical holders 220a, 220b, 220c, 220d, 220e can be adjusted to correspond to a desired beam profile. As such, although four optical holders 220a, 220b, 220c, 220d, 220e are depicted, in other embodiments, the optical bench assembly can have any number of optical holders, such as more or less than five optical holders (e.g., two, three, four, six, or the like). Additionally, the position of the optical holders 220a, 220b, 220c, 220d, 220e can be adjusted to a different orientation than as shown in FIG. 2.

The optical holders 220a, 220b, 220c, 220d, 220e may be coupled to sets of openings defined by the housing 210. Specifically, the housing 210 may define multiple sets of a first opening 214 and a second opening 216. Each set of the openings 214, 216 may be co-planar along the X-Y plane and can receive a portion of a corresponding optical holder 220a, 220b, 220c, 220d, 220e (e.g., the arms 320a, 320b, 320c of the first optical holder 220a) therewithin. For the sake of visual clarity, only a few of the openings 214, 216 are annotated with reference lines in FIG. 2.

The housing 210 may define any number of sets of openings 214, 216 extending along the length of the housing 210 along the Z-axis, such as more or less than what is shown in FIG. 2. Each set of openings 214, 216 may be separated from each other by between about 1 mm and 15 mm, such as between about 3 mm and 12 mm, such as between about 6 mm and 9 mm, or the like. Although each set of openings 214, 216 along the X-Y plane is depicted as including two openings 214, 216, in other embodiments, each set of openings may include more than two openings, such as three, four, or the like. In some embodiments, there may only be one opening for each optical holder to be coupled to. The second opening 216 may include a larger cross-sectional area along the X-Y plane than the first opening 214. This larger cross-sectional area may allow for more portions of the corresponding optical holder 220a, 220b, 220c, 220d, 220e to be positioned within, as will be discussed further below. However, in other embodiments, each of the openings may be a similar size. In yet other embodiments, the first opening may be larger than the second opening. A more detailed discussion of the engagement between the optical holders 220a, 220b, 220c, 220d, 220e and corresponding set of openings 214, 216 will be described below.

Each optical holder 220a, 220b, 220c, 220d, 220e can include any number of sets of openings 214, 216 positioned between each optical holder 220a, 220b, 220c, 220d, 220e. For example, the third optical holder 220c and fourth optical holder 220d may not include any sets of openings 214, 216 positioned between therebetween. In another example, two sets of openings 214, 216 may be between the fourth optical holder 220d and the fifth optical holder 220e. As such, the position of each optical holder 220a, 220b, 220c, 220d, 220e can be spaced relative to each other based on the number of sets of openings 214, 216 positioned between each optical holder 220a, 220b, 220c, 220d, 220e, as desired.

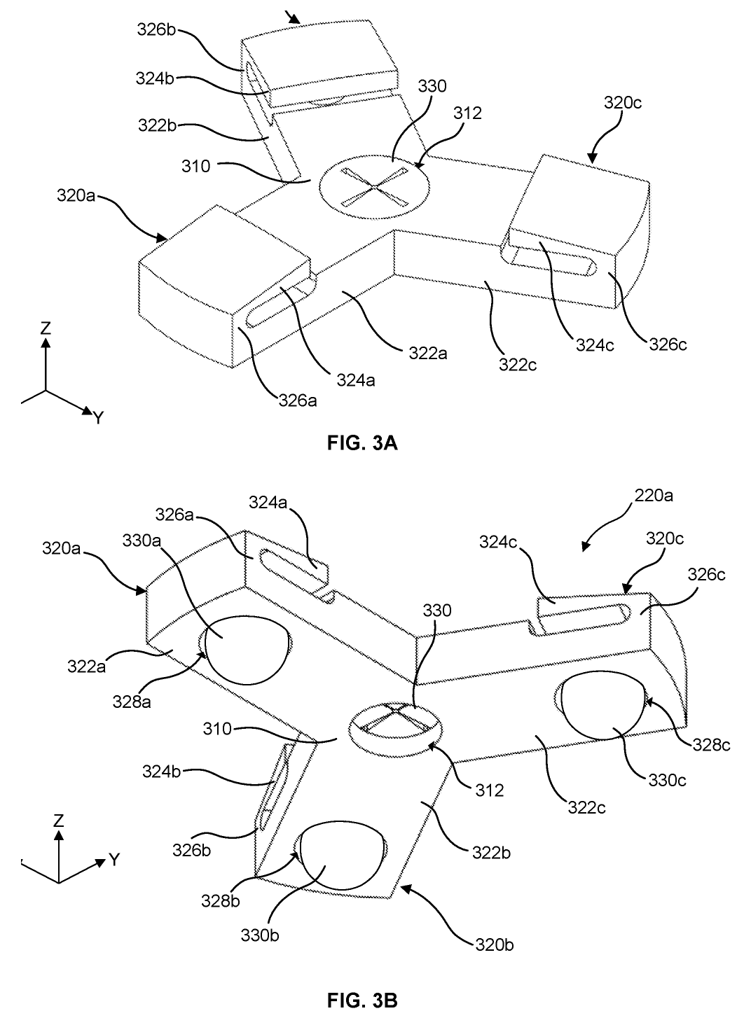

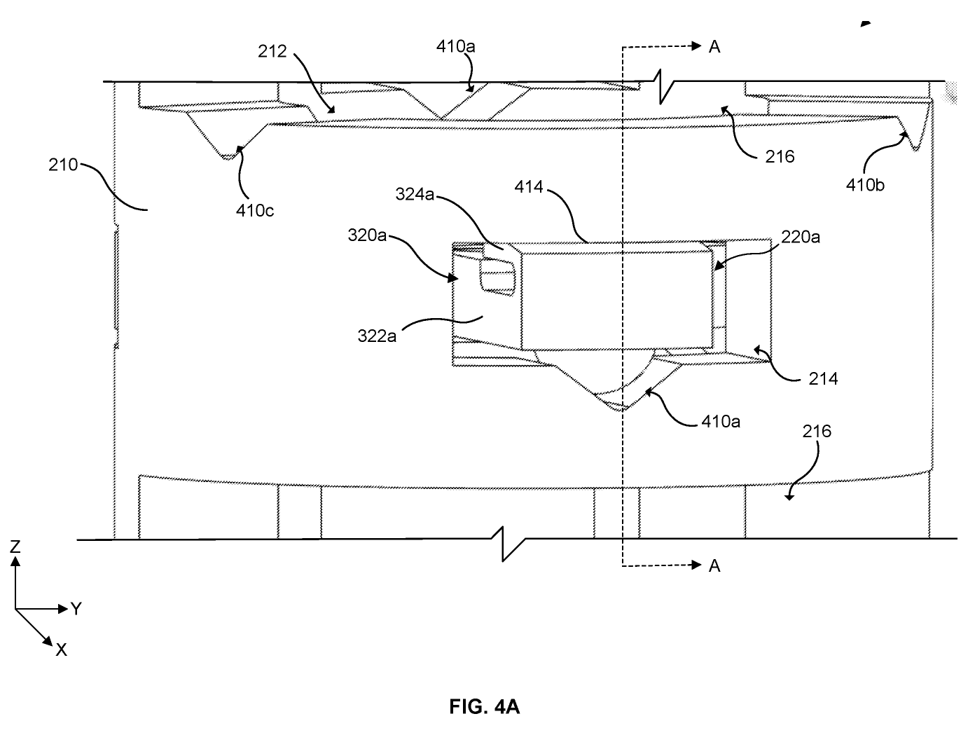

FIGS. 3A and 3B depict the first optical holder 220a. It is understood that the following description regarding the first optical holder 220a similarly applies to the other optical holders 220b, 220c, 220d, 220e. The first holder 220a may include a base portion 310 defining an optical aperture 312 that can house an optical element 340. The first optical holder 220a may include a first arm 320a, a second arm 320b, and a fourth arm 320c radially extending from the base portion 310. The three arms 320a, 320b, 320c may be spaced substantially equiangularly from each other (e.g., a 10% deviation from a completely equiangular angle of 120° from each other, a 5% deviation, a 2% deviation, a 1% deviation, or being completely equiangular from each other) along the X-Y plane. This number of arms 320a, 320b, 320c and substantially equiangular relationship between the arms 320a, 320b, 320c may be useful in centering the optical element 340 along a central axis of the channel 212 in the housing 210, as will be discussed further below. However, in other embodiments, the arms may be at any angle relative to each other along the X-Y plane. Additionally or alternatively, there may be more or less than three arms extending from the base portion, such as one arm, two arms, four arms, or the like.

Each arm 320a, 320b, 320c may include an arm body with a spring mechanism extending from the arm body to a distal end. Specifically, the first arm 320a can include a first arm body 322a and a first spring mechanism 324a extending from a first end 326a of the first arm body 322a, a second arm 320b can include a second arm body 322b and a second spring mechanism 324b extending from a second end 326b of the second arm body 322b, and a third arm 320c can include a third arm body 322c and a third spring mechanism 324c extending from a third end 326c of the third arm body 322c. The spring mechanisms 324a, 324b, 324c may be cantilever springs that can rotate about the ends 326a, 326b, 326c and are biased away from the arm bodies 322a, 322b, 322c.

In other embodiments, the spring mechanisms may be other types of springs, such as including other spring components (e.g., a compression spring, torsion spring, leaf spring, or the like) coupled to the arm bodies. In yet other embodiments, the spring mechanisms may extend from other portions of the corresponding arm bodies other than the ends, such as along an intermediate portion of the arm bodies. In one alternative embodiment, the spring mechanisms may be a leaf spring such that the spring mechanisms may not extend from the arm bodies to a distal end but, rather, form a leaf spring with both ends extending from the arm body. This leaf spring can be compressed toward the arm body along a central portion of the leaf spring. Using a leaf spring as the spring mechanism may provide an alternative means of installing the first optical holder, as discussed further below.

The spring mechanisms 324a, 324b, 324c may be oriented toward the base portion 310 such that, as described further below, when the arms 320a, 320b, 320c are inserted in the corresponding openings 214, 216 of the housing 210, the spring mechanisms 324a, 324b, 324c can more easily slide into the openings 214, 216. However, in other embodiments, the orientation of the spring mechanisms 324a, 324b, 324c may be different based on a desired direction of insertion into the housing 210. For example, in other embodiments, one or more of the spring mechanisms may be oriented in a direction away from the base portion. In one example, one or more of the spring mechanisms may extend from an intermediate portion of the arm body to a distal end in a direction facing away from the base portion.

The arm bodies 322a, 322b, 322c can each define an arm aperture to house a corresponding ball. Specifically, the first arm body 322a can define a first arm aperture 328a housing a first ball 330a, the second arm body 322b can define a second arm aperture 328b housing a second ball 330b, and the third arm body 322c can define a third arm aperture 328c housing a third ball 330c. The arm apertures 328a, 328b, 328c can be sized and shaped to receive the balls 330a, 330b, 330c, such as having a semi-spherical shape, a trihedral shape, a pyramidal shape, a frustoconical shape, or the like. The balls 330a, 330b, 330c can be adhered to the arm bodies 322a, 322b, 322c within the arm apertures 328a, 328b, 328c (e.g., with a vacuum-compatible adhesive or the like) such that the balls 330a, 330b, 330c are restricted in movement relative to the bodies 322a, 322b, 322c. In this manner, pressure applied against the balls 330a, 330b, 330c in a Z-direction (e.g., by the spring mechanisms 324a, 324b, 324c) is also applied to the arm bodies 322a, 322b, 322c and base portion 310. The arm bodies 322a, 322b, 322c can define the arm apertures 328a, 328b, 328c adjacent the ends 326a, 326b, 326c of each of the arm bodies 322a, 322b, 322c, however, in other embodiments, the arm apertures can be defined closer to the base portion than as shown in FIGS. 3B. In other embodiments, the arm bodies may define a notch extending along a length of the arm bodies and the balls may be at least partially received in the notch.

The spring mechanisms 324a, 324b, 324c can be vertically opposite the balls 330a, 330b, 330c (e.g., along the Z-axis) along the arm bodies 322a, 322b, 322c. In this manner, the spring mechanisms 324a, 324b, 324c can be depressed toward the balls 330a, 330b, 330c to engage the balls 330a, 330b, 330c. The spring mechanisms 324a, 324b, 324c can engage the balls 330a, 330b, 330c to move the arm bodies 322a, 322b, 322c and base portion 310 can be moved in a direction away from the spring mechanisms 324a, 324b, 324c, along the Z-axis. As will be discussed further below, this can facilitate the engagement of the balls 330a, 330b, 330c with other components.

The optical element 340 can be a multipole element capable of altering a beam profile of a charged particle beam. For example, the multipole element can be an electromagnetic element (e.g., capable of generating a magnetic field) or an electrostatic element (e.g., capable of generating an electric field) to alter the beam profile of the charged particle beam propagating through the multipole element. It may be beneficial for the multipole element to be an electrostatic element since an electrostatic element may require less space and less manufacturing complexity than with an electromagnetic element, which can require magnetic coils that can fluidly couple to a vacuum, as in conventional systems. As such, the multipole element being an electrostatic element can decrease the overall size of the optical bench assembly 130 and allow the optical bench assembly 130 to be positioned in the vacuum volume 145 of the beam column 110. However, in other embodiments, the multipole element may be an electromagnetic element. Although the optical element 340 is depicted as a quadrupole, in other embodiments, the optical element can be a dipole, sextupole, or other higher-order multipoles. In some embodiments, the optical element may include a charged particle lens, such as one or more einzel lenses (or a unipotential lens) or the like. The charged particle lens may be an electrostatic or electromagnetic charged particle lens.

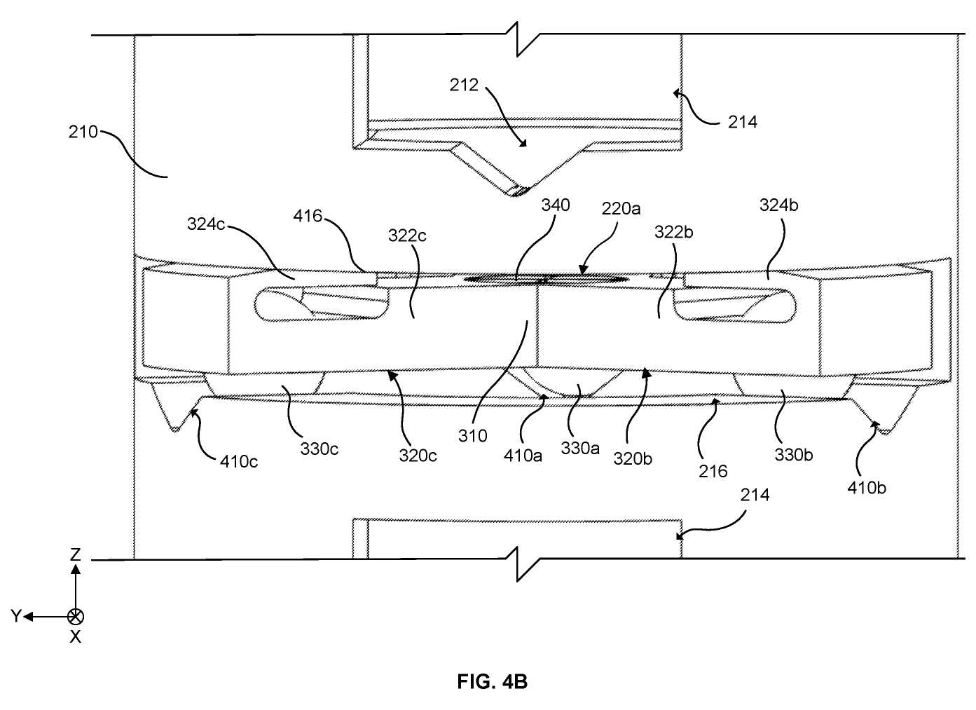

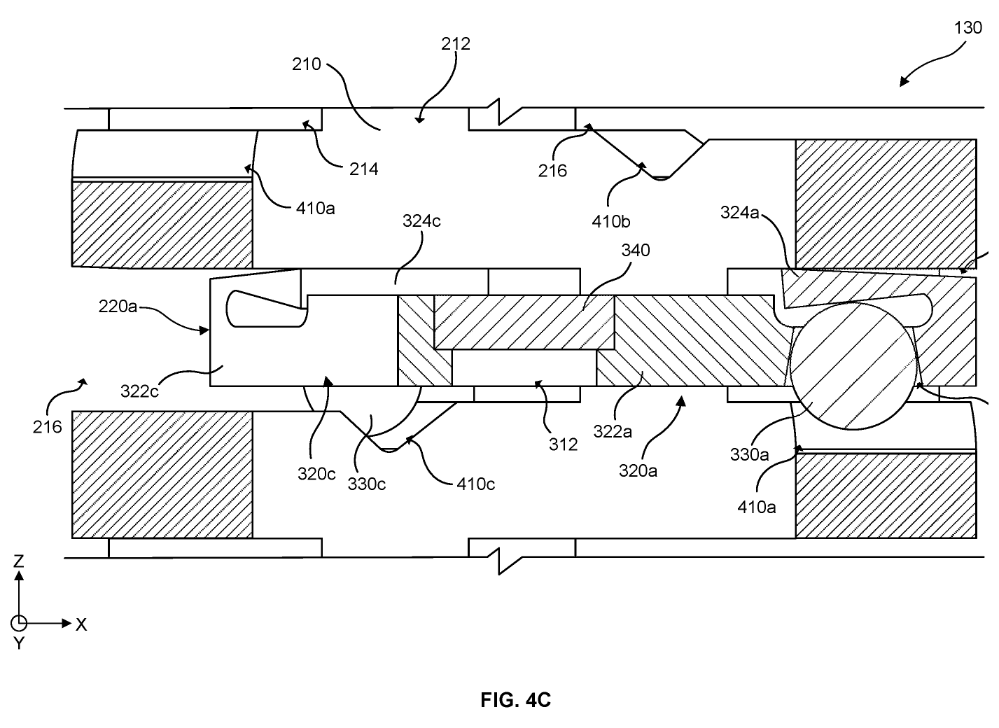

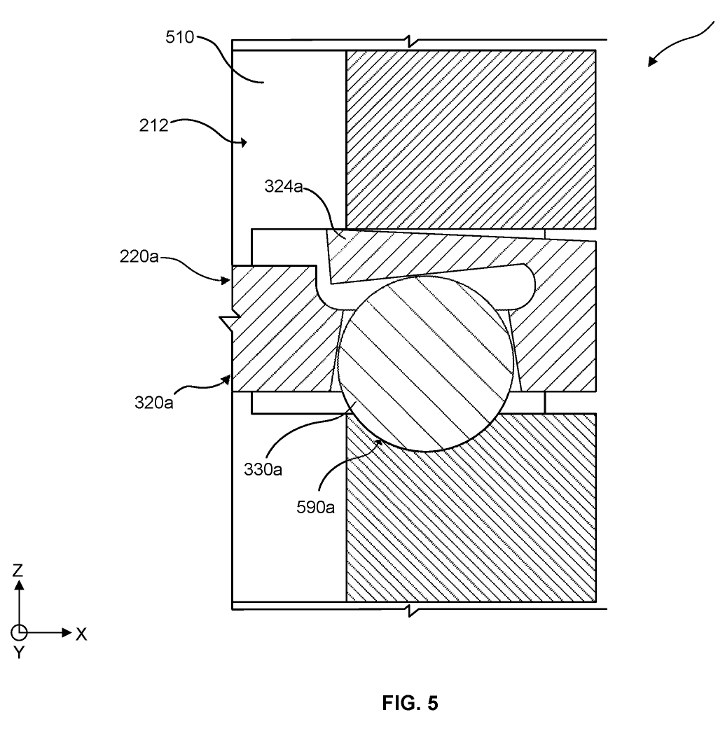

FIGS. 4A-4C depict the first optical holder 220a being coupled to the housing 210. As shown in FIG. 4A, the housing 210 can define a first notch 410a that receives the first ball 330a. The first notch 410a can partially define the first opening 214. As shown in FIG. 4B, the housing 210 can define a second notch 410b and a third notch 420c. The notches 410b, 410c can partially define the second opening 216. The notches 410a, 410b, 410c can be shaped as a V-notch and defined between two intersecting planar surfaces of the housing 210. However, in other embodiments, the notches can have other shapes, such as being spherical, conical, or the like. The balls 330a, 330b, 330c can be centered between the two intersecting planar surfaces when the balls 330a, 330b, 330c are received in the notches 410a, 410b, 410c. In other embodiments, the notches can have other shapes, such as a partially cylindrical shape, partially spherical shape, or the like. The notches 410a, 410b, 410c can be defined in the housing 210 in a direction oriented toward a center axis of the channel 212. However, in other embodiments, the notches can be defined in a direction off-center from a central axis of the channel. The notches 410a, 410b, 410c can be spaced substantially equiangularly from each other. As will be discussed below, this substantially equiangular relationship of the notches 410a, 410b, 410c from each other may assist in centering the optical element 330 in the channel 212. In yet other embodiments, the housing may not define a notch.

The first spring mechanism 324a may be compressed against the first ball 330a and the spring mechanisms 324b, 324c may be compressed against the balls 330b, 330c. The compression of the spring mechanisms 324a, 324b, 324c against the balls 330a, 330b, 330c may push the balls 330a, 330b, 330c into the notches 410a, 410b, 410c (and arm bodies 322a, 322b, 322c and base portion 310 in a Z-direction toward the 410a, 410b, 410c) such that the balls 330a, 330b, 330c are frictionally engaged with the intersecting planar surfaces defining the 410a, 410b, 410c. The first spring mechanism 324a can be held in place in this configuration by a first surface 414 that partially defines the first opening 214. The spring mechanisms 324b, 324c may be held in place in this configuration by a second surface 416 that partially defines the second opening 216. In this manner, the spring mechanisms 324a, 324b, 324c can help secure the position of the first optical holder 220a within the housing 210.

In this configuration, the optical element 330 can be centered in the channel 212 (e.g., concentric about a central axis of the channel 212) such that a charged particle beam can propagate through the channel 212 and through a center of the optical element 220. The other optical holders 220b, 220c, 220d, 220e can be similarly centered along the housing 210. In this manner, all the optical holders 220a, 220b, 220c, 220d, 220e (and corresponding optical elements 340 of each of the optical holders 220a, 220b, 220c, 220d, 220e) may be substantially concentrically aligned with each other and the channel 212. For example, a central axes of the optical holders 220a, 220b, 220c, 220d, 220e and channel 212 may be concentrically aligned with each other with less than about a 5 micron deviation from each other, a 3 micron deviation, a 2 micron deviation, a 1 micron deviation, or with no deviation.

This central alignment of the optical holders 220b, 220c, 220d, 220e can be facilitated by the process of installing the optical holders 220b, 220c, 220d, 220e to the housing 210. For example, to couple the first optical holder 220a to the housing 210, the arms 320a, 320b, 320c can be inserted into the openings 214, 216. In particular, turning to FIG. 4B, the first arm 320a and base portion 310 is first inserted through the second opening 216 from exterior of the housing 210 toward the channel 212 until the first arm 320a and base portion 310 exits the second opening 216 into the channel 212. The first arm 320a is then inserted, from within the channel 212, into the first opening 214 and, at the same time, the other arms 320b, 320c are inserted into the second opening 216. As the arms 320a, 320b, 320c are inserted into the corresponding openings 214, 216, the balls 330a, 330b, 330c are inserted into the corresponding notches 410a, 410b, 410c.

Due to the substantially equiangular relationship of the arms 320a, 320b, 320c to each other about the base portion 310 (and, therefore, the corresponding substantially equiangular relationship of the balls 330a, 330b, 330c to each other) and the substantially equiangular relationship of the notches 410a, 410b, 410c to each other about the channel 212, the first optical holder 220a can be centered with the channel 212 as the arms 320a, 320b, 320c are inserted into the corresponding openings 214, 216 and the balls 330a, 330b, 330c are inserted into the corresponding notches 410a, 410b, 410c. Specifically, as the first ball 330a slides along a central axis of the first notch 410a in a direction away from the channel 212, the other balls 330b, 330c sliding within the other notches 410b, 410c toward the channel 212 will, due to the non-parallel angular of the notches 410a, 410b, 410c to each other, start moving in a direction that deviates from the corresponding central axes of the other notches 410b, 410c. As the balls 330b, 330c deviate from the central axes of the notches 410b, 410c, the balls 330b, 330c may start interfacing in an X- and Y- direction against the intersecting planar surfaces of the housing 210 that defines the notches 410b, 410c with increasing pressure. As such, once the first arm 320a is received within the first opening 214, and the first ball 330a slides within the first notch 410a, to a certain distance, the movement of the other balls 330b, 330c may be restricted along the X-Y plane by being pressed against the intersecting planar surfaces of the housing 210 that defines the notches 410b, 410c. The first optical holder 220a (and, by extension, the optical element 330) may be centered along the channel 212 once the movement of the balls 330b, 330c are restricted along the X-Y plane and the first ball 330a is restricted in linear movement along the first notch 410a. Such restrictions in movement can indicate that the balls 330a, 330b, 330c are aligned and centered.

As the first arm 320a is received in the first opening 214, the first spring mechanism 324a is pushed against the ball 330a by the first surface 414 and the spring mechanisms 324b, 324c are pushed against the balls 330b, 330c by the second surface 416 that partially defines the second opening 216. The spring mechanisms 324a, 324b, 324c push the balls 330a, 330b, 330c into the notches 410a, 410b, 410c to apply further pressure to the balls 330a, 330b, 330c and increase the friction engagement between the balls 330a, 330b, 330c and notches 410a, 410b, 410c, as described above. As the spring mechanisms 324a, 324b, 324c pushes the balls 330a, 330b, 330c toward the notches 410a, 410b, 410c, the arm bodies 322a, 322b, 322c and base portion 310 are also pushed in a in a Z-direction toward the notches 410a, 410b, 410c. This engagement and increased pressure can further minimize movement of the first optical holder 220a along the X-Y plane once the first optical holder 220a is centered in the housing 210.

Prior to inserting the spring mechanisms 324b, 324c into the second opening 216, the spring mechanisms 324b, 324c may be pre-emptively pushed down to allow for the distal ends of the spring mechanisms 324b, 324c to slide into the second opening 216 without catching against the exterior surface of the housing 210. However, in other embodiments, as noted above, the second and third spring mechanisms may be oriented in a direction facing away from the base portion. This may be beneficial as, during installation of the first optical holder, the second and third spring mechanisms can more easily slide under the second surface that partially defines the second opening without having to compress the second and third spring mechanisms prior to inserting the second and third spring mechanisms into the second opening. In this manner, all the spring mechanisms may be inserted into the corresponding first and second openings without catching against an exterior surface of the housing. In a yet further embodiment, the second and third spring mechanisms may be a leaf spring without a distal end extending from the corresponding arm bodies, rather than a cantilever spring. As the leaf springs do not include distal ends that can catch on a surface of the housing, the leaf springs can be compressed to push against the ball (and the corresponding arm bodies and base portion) when the optical holders are slid into the housing without requiring pre-emptive compression of the leaf spring.

The first optical holder 220a can be decoupled and removed from the housing 210 by pushing the first arm 320a from the first opening 214 and back out into the channel 212. As the first arm 320a is pushed into the channel 212, the other arms 320b, 320c may be pushed out of the second opening 216 to exterior of the housing 210. The first arm 320a may then be pushed out of the second opening 216 to exterior of the housing 210. Prior to pushing the first arm 320a out of the second opening 216, the first spring mechanism 324a may be compressed to prevent a distal end of the first spring mechanism 324a from catching against the interior surface of the housing 210 that defines the channel 212. However, in other embodiments, the first spring mechanism may be oriented in a direction facing away from the base portion and/or the first spring mechanism may be a leaf spring such that the first spring mechanism does not need to be compressed before pushing the first spring mechanism out of the second opening.

Based on the process above, the first optical holder 220a can be inserted and removed from the housing 210 as desired. The other optical holders 220b, 220c, 220d, 220e can be inserted and removed from the housing 210 in a similar manner. In this manner, the optical holders 220a, 220b, 220c, 220d, 220e can be easily inserted and removed (e.g., to be exchanged with other optical holders or moved to different positions along the housing 210) while being consistently aligned and fixed to a central axis of the channel 212. This modularity increases the ability of the optical bench assembly 130 to create a charged particle beam having a specific and custom beam profile. In some embodiments, the entire optical bench assembly 130 can be removed with a different optical bench assembly having a different configuration of optical holders.

The housing 210, and the base portion 310 and arms 320a, 320b, 320c of the optical holders 220a, 220b, 220c, 220d, 220e can be made of a metal or plastic material, such as non-magnetic material. For example, the metal material may include copper, aluminum, brass, stainless steel, gold, or the like. The plastic materials may include polyethylene, polypropylene, polytetrafluoroethylene, or the like.

As noted above, the housing 210 may define the notches 410a, 410b, 410c to have other shapes. For example, FIG. 5 depicts an optical bench assembly 530 with a housing 510 defining a first notch 590a receiving the first ball 330a along a similar section plane as in FIG. 4C. The first notch 590a may have a spherical shape sized and shaped to receive the first ball 330a. The first spring mechanism 324a may push the first ball 330a into the spherical first notch 590a such that the first ball 330a resists moving along the X-Y plane until a threshold amount of force is applied to push the first ball 330a out of the first notch 590a. Although not shown in FIG. 5, the other notches defined by the housing 510 may include a similar spherical shape corresponding to the other balls. The housing 510 may define the position of the spherical notches such that, once the balls are received in the spherical notches, the first optical holder 220a can be aligned with the channel 212 (e.g., aligned with the beam axis of the charged particle beam). In this manner, the first optical holder 220a can be installed within the housing 510, as described above, until the balls of the first optical holder 220a engages with corresponding spherical notches similar to the engagement between the first ball 330a and the spherical first notch 590a. This engagement between the balls and the notches in the optical bench assembly 530 can ensure that the first optical holder 220a is aligned with the channel 212 while also providing a tactile sensation to a user that the first optical holder 220a is aligned with the channel 212. In yet other embodiments, the notch can have a conical shape.

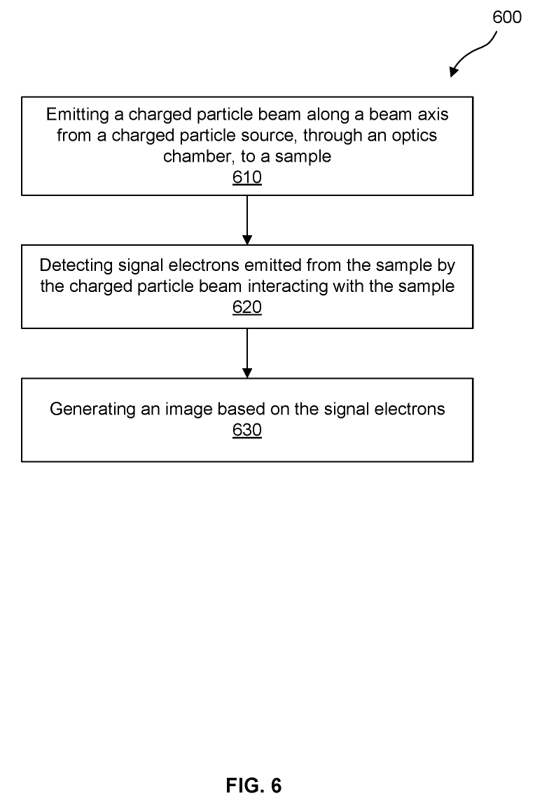

FIG. 6 depicts an example flowchart showing a process 600 for generating an image. Unless noted otherwise, the flowchart in FIG. 6 will be described with reference to the charged particle system 100 shown in FIG. 1 and the optical bench assembly shown in FIGS. 4A-4C. At least some of the below operation of the components of the charged particle system 100 can be performed under the control of or by the computer system 190. It is understood that features ending in like reference numerals as features discussed above are similar, except as noted below.

Block 610 may include emitting a charged particle beam along a beam axis from a charged particle source, through an optics chamber, to a sample. For example, a charged particle beam (e.g., an electron beam or the like) can be emitted from the source section 102 through the beam column 110 and onto a sample in the objective section 115. The charged particle beam may propagate along a beam axis through an optics bench assembly 130 positioned in the vacuum volume 145 of the beam column 110 before propagating onto the sample.

As shown in FIG. 2, the optics bench assembly 130 can include a housing 210 and optical holders 220a, 220b, 220c, 220d, 220e coupled to the housing 210 within openings 214, 216. Each of the optical holders 220a, 220b, 220c, 220d, 220e can include an optical element 340 (e.g., a multipole element) that is substantially aligned with the channel 212 of the housing 210. Turning to FIGS. 4A-4C, the first optical holder 220a can include a base portion 310 and arms 320a, 320b, 320c extending from the base portion 310. The arms 320a, 320b, 320c may be coupled to the openings 214, 216 through a friction engagement between the balls 330a, 330b, 330c positioned between the spring mechanisms 324a, 324b, 324c and the notches 410a, 410b, 410c. This configuration between the first optical holder 220a and the housing 210 can align the optical element 340 of the first optical holder 220a with a central axis of the channel 212 (e.g., the beam axis of the charged particle beam). In other embodiments, turning to FIG. 5, the first optical holder 220a can be coupled to the housing 510 through the first spring mechanism 324a pushing the ball 330a into the spherical first notch 590a to similarly align the first optical holder 220a with a central axis of the channel 212. Turning back to FIGS. 4A-4C, each of the other optical holders 220b, 220c, 220d, 220e can be similarly installed. In this manner, each of the optical holders 220a, 220b, 220c, 220d, 220e can be aligned with the central axis of the channel 212 such that the beam profile of the charged particle beam propagating through the optics bench assembly 130 can be adjusted by the optical elements 340 of each of the optical holders 220a, 220b, 220c, 220d, 220e prior to the charged particle beam propagating onto the sample.

Block 620 may include detecting signal electrons emitted from the sample by the charged particle beam interacting with the sample.

Block 630 may include generating an image based on the signal electrons. Once the image is generated, open or more of the optical holders 220a, 220b, 220c, 220d, 220e can be removed from the housing 210, and exchanged with another optical holder and/or repositioned along the housing 210. In some embodiments, the entire optical bench assembly 130 can be removed with a different optical bench assembly having a different configuration of optical holders.

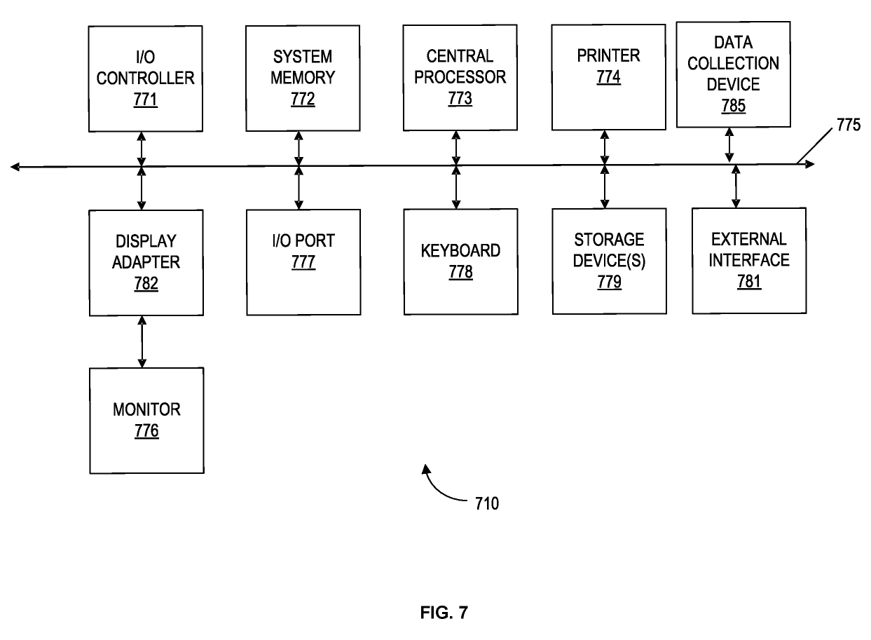

Any of the computer systems mentioned herein may utilize any suitable number of subsystems. Examples of such subsystems are shown in FIG. 7 in computer system 710, which is an example of the computer system 190. In some embodiments, a computer system includes a single computer apparatus, where the subsystems can be the components of the computer apparatus. In other embodiments, a computer system can include multiple computer apparatuses, each being a subsystem, with internal components. A computer system can include desktop and laptop computers, tablets, mobile phones and other mobile devices.

The subsystems shown in FIG. 7 are interconnected via a system bus 775. Additional subsystems such as a printer 774, keyboard 778, storage device(s) 779, monitor 776 (e.g., a display screen, such as an LED), which is coupled to display adapter 782, and others are shown. Peripherals and input/output (I/O) devices, which couple to I/O controller 771, can be connected to the computer system by any number of means known in the art such as input/output (I/O) port 777 (e.g., USB, FireWire^{®}). For example, I/O port 777 or external interface 781 (e.g., Ethernet, Wi-Fi, etc.) can be used to connect computer system 710 to a wide area network such as the Internet, a mouse input device, or a scanner. The interconnection via system bus 775 allows the central processor 773 to communicate with each subsystem and to control the execution of a plurality of instructions from system memory 772 or the storage device(s) 779 (e.g., a fixed disk, such as a hard drive, or optical disk), as well as the exchange of information between subsystems. The system memory 772 and/or the storage device(s) 779 may embody a computer readable medium. Another subsystem is a data collection device 785, such as a camera, microphone, accelerometer, and the like. Any of the data mentioned herein can be output from one component to another component and can be output to the user.

A computer system can include a plurality of the same components or subsystems, e.g., connected together by external interface 781, by an internal interface, or via removable storage devices that can be connected and removed from one component to another component. In some embodiments, computer systems, subsystem, or apparatuses can communicate over a network. In such instances, one computer can be considered a client and another computer a server, where each can be part of a same computer system. A client and a server can each include multiple systems, subsystems, or components.

Aspects of embodiments can be implemented in the form of control logic using hardware circuitry (e.g., an application specific integrated circuit or field programmable gate array) and/or using computer software stored in a memory with a generally programmable processor in a modular or integrated manner, and thus a processor can include memory storing software instructions that configure hardware circuitry, as well as an FPGA with configuration instructions or an ASIC. As used herein, a processor can include a single-core processor, multi-core processor on a same integrated chip, or multiple processing units on a single circuit board or networked, as well as dedicated hardware. Based on the disclosure and teachings provided herein, a person of ordinary skill in the art will know and appreciate other ways and/or methods to implement embodiments of the present disclosure using hardware and a combination of hardware and software.

Any of the software components or functions described in this application may be implemented as software code to be executed by a processor using any suitable computer language such as, for example, Java, C, C++, C#, Objective-C, Swift, or scripting language such as Perl or Python using, for example, conventional or object-oriented techniques. The software code may be stored as a series of instructions or commands on a computer readable medium for storage and/or transmission. A suitable non-transitory computer readable medium can include random access memory (RAM), a read only memory (ROM), a magnetic medium such as a hard-drive or a floppy disk, or an optical medium such as a compact disk (CD) or DVD (digital versatile disk) or Blu-ray disk, flash memory, and the like. The computer readable medium may be any combination of such devices. In addition, the order of operations may be re-arranged. A process can be terminated when its operations are completed, but could have additional steps not included in a figure. A process may correspond to a method, a function, a procedure, a subroutine, a subprogram, etc. When a process corresponds to a function, its termination may correspond to a return of the function to the calling function or the main function.

Such programs may also be encoded and transmitted using carrier signals adapted for transmission via wired, optical, and/or wireless networks conforming to a variety of protocols, including the Internet. As such, a computer readable medium may be created using a data signal encoded with such programs. Computer readable media encoded with the program code may be packaged with a compatible device or provided separately from other devices (e.g., via Internet download). Any such computer readable medium may reside on or within a single computer product (e.g., a hard drive, a CD, or an entire computer system), and may be present on or within different computer products within a system or network. A computer system may include a monitor, printer, or other suitable display for providing any of the results mentioned herein to a user.

Any of the methods described herein may be totally or partially performed with a computer system including one or more processors, which can be configured to perform the steps. Any operations performed with a processor (e.g., aligning, determining, comparing, computing, calculating) may be performed in real-time. The term “real-time” may refer to computing operations or processes that are completed within a certain time constraint. The time constraint may be 1 minute, 1 hour, 1 day, or 7 days. Thus, embodiments can be directed to computer systems configured to perform the steps of any of the methods described herein, potentially with different components performing a respective step or a respective group of steps. Although presented as numbered steps, steps of methods herein can be performed at a same time or at different times or in a different order. Additionally, portions of these steps may be used with portions of other steps from other methods. Also, all or portions of a step may be optional. Additionally, any of the steps of any of the methods can be performed with modules, units, circuits, or other means of a system for performing these steps.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as "bottom” or "top" and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a "bottom" surface can then be oriented "above" other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In some implementations, operations or processing may involve physical manipulation of physical quantities. Typically, although not necessarily, such quantities may take the form of electrical or magnetic signals capable of being stored, transferred, combined, compared, or otherwise manipulated. It has proven convenient at times, principally for reasons of common usage, to refer to such signals as bits, data, values, elements, symbols, characters, terms, numbers, numerals, or the like. It should be understood, however, that all of these or similar terms are to be associated with appropriate physical quantities and are merely convenient labels. Unless specifically stated otherwise, as apparent from the discussion herein, it is appreciated that throughout this specification discussions utilizing terms such as “processing,” “computing,” “calculating,” “determining,” or the like refer to actions or processes of a specific apparatus, such as a special purpose computer, special purpose computing apparatus or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. Optical bench assembly configured to be positioned in an optics chamber of a charged particle system, comprising:
a housing defining a plurality of openings and a channel defining a beam axis for a charged particle beam; and
a plurality of optical holders, wherein:
each optical holder of the plurality of optical holders includes a base portion and one or more arms extending from the base portion;
the one or more arms of each optical holder is removably mountable to the housing within a first opening of the plurality of openings;
the base portion of each optical holder is configured to house a multipole element; and
the base portion of each optical holder is positionable in the channel such that each multipole element is aligned with each other along the beam axis.

2. The optical bench assembly of claim 1, wherein the one or more arms includes a plurality of arms.

3. The optical bench assembly of claim 2, wherein a first arm of the plurality of arms is removably mountable within the first opening and a second arm of the plurality of arms is removably mountable within a second opening of the plurality of openings.

4. The optical bench assembly of claim 3, wherein the second opening includes a larger cross-sectional area than the first opening.

5. The optical bench assembly of claim 4, wherein a third arm of the plurality of arms is removably mountable within the second opening.

6. The optical bench assembly of claim 1, wherein each optical holder of the plurality of optical holders includes a ball received in the one or more arms.

7. The optical bench assembly of claim 6, wherein the one or more arms includes a spring mechanism configured to engage the ball.

8. The optical bench assembly of claim 7, wherein the spring mechanism is one of a cantilever or leaf spring.

9. The optical bench assembly of claim 6, wherein the housing defines a notch configured to receive the ball.

10. The optical bench assembly of claim 1, wherein the multipole element includes an electrostatic multipole element.

11. The optical bench assembly of claim 10, wherein the electrostatic multiple element includes one or more electrostatic einzel lenses.

12. A charged particle system comprising:
a charged particle source configured to emit a charged particle beam along a beam axis; and
an optics chamber in fluid communication with the charged particle source, wherein the optics chamber includes an optical bench assembly comprising:
a housing defining a plurality of opening and a channel aligned with the beam axis;
an optical holder including a base portion and one or more arms extending from the base portion, wherein a first arm of the one or more arms are coupled to the housing within a first opening of the plurality of openings and the base portion is positioned in the channel; and
a multipole element housed in the base portion and aligned with the beam axis.

13. The charged particle system of claim 12, wherein:
the one or more arms includes a plurality of arms; and
a first arm of the plurality of arms is removably mountable within the first opening and a second arm of the plurality of arms is removably mountable within a second opening of the plurality of openings.

14. The charged particle system of claim 13, wherein each arm of the plurality of arms is substantially equiangular from each other about the base portion.

15. The charged particle system of claim 10, wherein:
the optics chamber defines a vacuum volume configured to be held under vacuum; and
the optical bench assembly is positioned in the vacuum volume.

16. The charged particle system of claim 12, wherein each optical holder of the plurality of optical holders includes a ball received in the one or more arms.

17. The charged particle system of claim 16, wherein the one or more arms includes a spring mechanism configured to engage the ball.

18. The charged particle system of claim 16, wherein the housing defines a notch configured to receive the ball.

19. The charged particle system of claim 12, wherein the multipole element includes an electrostatic multipole element.

20. An optical holder configured to be positioned in an optical bench assembly of a charged particle system, comprising:
a plurality of balls;
a base portion defining an optical aperture;
a plurality of arms extending from the base portion, wherein:
each arm of the plurality of arms defines an arm aperture and includes a lever mechanism;
each ball of the plurality of balls is positioned in the aperture of each arm; and
the lever mechanism of each arm is configured to engage the ball; and
an optical element housed in the optical opening.
